(19) United States
(12) Patent Application Publication
(10) Pub. No.: US 2026/0126505 A1
(43) Pub. Date: May 7, 2026

(54) Quantitative Material Characterization of an Object

(71) Applicant: Siemens Healthineers AG, Forchheim (DE)

(72) Inventors: Laura Pfaff, Nürnberg (DE); Tobias Würfl, Erlangen (DE); Marcel Dominik Nickel, Herzogenaurach (DE); Moritz Zaiss, Nürnberg (DE); Simon Weinmüller, Erlangen (DE); Jonathan Endres, Erlangen (DE)

(73) Assignee: Siemens Healthineers AG, Forchheim (DE)

(21) Appl. No.: 19/377,605

(22) Filed: Nov. 3, 2025

(30) Foreign Application Priority Data
Nov. 4, 2024 (EP) 24210519.5

(51) Int. Cl. G01R 33/56; G01R 33/48; G01R 33/50

(52) U.S. Cl. CPC G01R 33/5608; G01R 33/4818; G01R 33/50

(57) ABSTRACT

For material characterization, first and second measured MRI data representing an object and corresponding first and second sequence descriptions may be received. For each iteration, first and second simulated MRI data may be generated according to the sequence descriptions based on a model including model values for at least one material parameter. An error may be determined, which depends on a deviation of the simulated MRI data from the measured MRI data. The model may be adapted based on the error. For an initial iteration, the model corresponds to an initial model and otherwise it corresponds to the adapted model of the preceding iteration. The quantitative material characterization may be determined based on the adapted model of a final iteration of the two or more iterations.

### CROSS REFERENCE TO RELATED APPLICATIONS

This patent application claims priority to European Patent Application No. 24210519.5, filed Nov. 4, 2024, which is incorporated herein by reference in its entirety.

### BACKGROUND

The present disclosure is directed to a computer-implemented method for determining a quantitative material characterization of an object, wherein first measured magnetic resonance imaging, MRI, data representing the object is received. The disclosure is further directed to a data processing system for carrying out said computer-implemented method, to a corresponding method for quantitative MRI, to an MRI system comprising said data processing system, and to corresponding computer program products.

Quantitative MRI, qMRI, plays an important role in medical imaging by providing quantitative, objective measurements of tissue properties, such as relaxation times or proton density. Unlike conventional MRI, which produces images with qualitative contrasts only, qMRI aims to derive material parameters that have direct relevance to the underlying tissue composition and microstructure. This shift towards quantification enhances the precision and reproducibility of MRI examinations and facilitates comparisons across different subjects and scanners.

Various approaches have been suggested for the quantification of tissue parameters. However, most of them require excessive scan time, which poses challenges for their practical implementation in clinical settings and provides limited reproducibility.

In acquisition processes, parametric mapping frequently involves a delicate balance between precision and accuracy versus the time required for measurement. Precise and accurate quantification often relies on “clean” acquisitions of multiple contrasts that only depend on few parameters. These parameters are later determined by fitting the different contrasts to a signal model. Prime examples include inversion or saturation recovery measurements for determining T1 and T2, which are often considered as gold standard.

Accelerated acquisition methods frequently require trade-offs in contrast accuracy. For instance, variable flip angle, vFA, T1 mapping often relies on less precise steady states to expedite the process.

Magnetic resonance fingerprinting, MRF, is an alternative approach in qMRI, which simultaneously acquires multiple parameters in a single scan. Instead of isolating specific sequences for individual measurements, MRF aims to generate a “fingerprint” of tissue properties, allowing for more efficient and comprehensive quantification. The underlying idea is based on a complete Bloch simulation of the applied acquisition sequence diagram for an imaged voxel. A significant compromise in MRF lies in the calculation of the signal evolution in a given voxel from the acquired k-space data. Since many samples for the signal evolution are required and a complete optimization of the whole volume is intractable with conventional reconstruction methods, typically simple regridding reconstructions are done with high undersampling. The method relies on the hope that corresponding undersampling artifacts average out in the voxel-wise dictionary matching. Moreover, establishing standardized dictionaries and protocols across different scanners and sites is a challenge for widespread clinical adoption.

MRI simulators are software tools designed to replicate the processes and outcomes of MRI without the need for an actual MRI scanner. They work by using a model for an object and simulations to emulate the physical principles involved in MRI. Some simulators are based on solving the Bloch equations directly, as for example described in the publication of H. Benoit-Cattin et al.: “The SIMRI project: a versatile and interactive MRI simulator.”, Journal of Magnetic Resonance, 173(1), 97-115.

Others rely on the extended phase graph algorithm, as explained in S. Rakshit et al.: “GPU-accelerated extended phase graph algorithm for differentiable optimization and learning.” Proc. Intl. Soc. Mag. Reson. Med. 29 (2021), available at https://somnathrakshit.github.io/projects/project-mri-sim-py-epg/3754.html (retrieved Oct. 11, 2024).

MRzero is a comprehensive framework that emulates an MRI pipeline, encompassing sequence and phantom definition, signal simulation, and image reconstruction, as described in A. Loktyushin et al.: “MRzero-Automated discovery of MRI sequences using supervised learning.”, Magnetic Resonance in Medicine, 86: 709-724 and H. Dang et al.: “MR-zero meets RARE MRI: Joint optimization of refocusing flip angles and neural networks to minimize T2-induced blurring in spin echo sequences.”, Magnetic Resonance in Medicine, 90(4): 1345-1362. At its core, MRzero incorporates a phase distribution graph, PDG, simulator inspired by the EPG concept, as described in J. Endres et al.: “Phase distribution graphs for fast, differentiable, and spatially encoded Bloch simulations of arbitrary MRI sequences.” Magnetic Resonance in Medicine, 92, 10.

Sequence descriptions for MRI acquisition sequences can, for example, be provided in the form of files following the pulseq standard, as described in K. J. Layton et al.: “Pulseq: A rapid and hardware-independent pulse sequence prototyping framework.” Magnetic Resonance in Medicine, 77(4):1544-1552.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows schematically an exemplary embodiment of an MRI system according to the disclosure; and

FIG. 2 shows a schematic block diagram of an exemplary embodiment of a computer-implemented method for determining a quantitative material characterization of an object according to the disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the present disclosure to provide a method and system for determining a quantitative material characterization of an object based on MRI data. Conventional qualitative MRI acquisition sequences may be used.

The disclosure is based on the idea to simulate MRI data according to at least two acquisition sequences based on a model for the object to be imaged and to iteratively adapt the model based on a deviation of the simulated MRI data from the respective measured MRI data.

According to an aspect of the disclosure, a computer-implemented method for determining a quantitative material characterization of an object is provided. Therein, first measured magnetic resonance imaging, MRI, data representing the object is received and a first sequence description specifying a first acquisition sequence used for generating the first measured MRI data is received. Second measured MRI data representing the object is received and a second sequence description specifying a second acquisition sequence used for generating the second measured MRI data is received, wherein the second acquisition sequence is, in particular, different from the first acquisition sequence. For each iteration of two or more iterations, the following steps i) to iv) are carried out.

In step i), first simulated MRI data may be generated by simulating an MRI acquisition according to the first sequence description based on a model for the object comprising respective model values for at least one material parameter of the object. In step ii), second simulated MRI data may be generated by simulating an MRI acquisition according to the second sequence description based on the model. In step iii), an error may be determined, which depends on a deviation of the first simulated MRI data from the first measured MRI data and on a deviation of the second simulated MRI data from the second measured MRI data. In step iv), the model may be adapted by adapting the model values depending on the error.

The two or more iterations comprise an initial iteration and a final iteration. Optionally, the two or more iterations comprise one or more subsequent intermediate iterations following the initial iteration and the final iteration follows the intermediate iterations in this case. If the respective iteration corresponds to the initial iteration, the model of the respective iteration corresponds to an initial model for the object comprising respective predefined initial model values for the at least one material parameter, and otherwise the model of the respective iteration corresponds to the adapted model of a respective preceding iteration.

In other words, the model used in steps i) and ii) of the initial iteration is the initial model and the model used in steps i) and ii) of the final iteration and, if applicable, the one or more intermediate iterations, is the adapted model of the respective preceding iteration.

The quantitative material characterization may be determined depending on the adapted model of the final iteration of the two or more iterations. In particular, the quantitative material characterization is given by the adapted model of the final iteration or by the at least one material parameter of the adapted model of the final iteration or the quantitative material characterization may be computed or derived from the at least one material parameter of the adapted model.

Unless stated otherwise, all steps of the computer-implemented method may be performed by a data processing system, which may comprise at least one data processing device (e.g., processor). In particular, the at least one data processing device may be configured or adapted to perform the steps of the computer-implemented method. For this purpose, the at least one data processing device may for example store a computer program comprising instructions which, when executed by the at least one data processing device, cause the at least one data processing device to execute the computer-implemented method. The expressions “data processing system” and “at least one data processing device” may be used interchangeably, here and in the following. This holds also for respective expressions derived therefrom.

In case the at least one data processing device may comprise two or more data processing devices, certain steps carried out by the at least one data processing device may also be understood such that different data processing devices carry out different steps or different parts of a step. In particular, it is not required that each data processing device carries out the steps completely. In other words, carrying out the steps may be distributed amongst the two or more data processing devices.

In an exemplary embodiment, generating the first and the second measured MRI data is not part of the computer-implemented method according to the disclosure. However, from each implementation of the computer-implemented method, a respective implementation of a method for determining a quantitative material characterization of an object, which is not purely computer-implemented, is obtained by including respective steps of generating the first and the second measured MRI data. Such a method may also be denoted as method for quantitative MRI, qMRI.

The total number of the two or more iterations is not necessarily predefined. In particular, the two or more iterations may be terminated after the final iteration of the two or more iterations, wherein the error of the final iteration is equal to or less than a predefined maximum error.

In other words, it may be provided that, if it is found in any iteration except for the initial iteration that the error computed in step iii) of the respective iteration is equal to or less than the maximum error, then said iteration is the final iteration by definition and no further iteration is carried out.

In other words, carrying out the two or more iterations corresponds to an optimization of an objective function, which is given by or depends on the error, wherein the at least one material parameter corresponds to the optimization variable or optimization variables. The exact way how the at least one material parameter is adapted to adapt the model depends on the actual optimization method used. Known optimization methods like gradient descent methods may be used, for example.

Here and in the following, measured MRI data can be understood as data, which is generated by an MRI device applying a respective MRI acquisition sequence while the object is located in the respective target region of the MRI device. The acquisition sequences, in particular the first acquisition sequence and the second acquisition sequence, are not necessarily specifically adapted for the purpose of qMRI. In particular, the acquisition sequences, in particular the first acquisition sequence and the second acquisition sequence, are not specifically adapted for the purpose of qMRI but correspond to conventional MRI acquisition sequences or, in other words, to MRI acquisition sequences for qualitative MRI.

Here and in the following, simulated MRI data can be understood as data, which is generated by a computer algorithm, which may be implemented in software and/or in hardware, which is adapted or designed, given the respective sequence description, to simulate the physical processes of the MR measurement for the object based on the model for the object. The computer algorithm may for example be denoted as an MRI simulator. A known MRI simulator, for example one of the MRI simulators mentioned in the introductory part of the present disclosure, may be used for this purpose. The respective sequence description, in particular the first sequence description and the second sequence description, may for example be provided according to the pulseq standard or according to another suitable standard.

The exact form of the model may depends on the actually used MRI simulator. For example, the model may comprise or be given by a respective three-dimensional parameter map for each material parameter of the at least one material parameter comprising the respective model values. In particular, the model, for example the three-dimensional parameter maps, may describe the spatial distribution of the values for each of the at least one material parameter for the object. The initial model or the initial model values, respectively, may be predefined default values, for example assuming a constant spatial distribution of the at least one material parameter within the object. Alternatively, more realistic estimated or empirically determined spatial distributions may be used for the initial model.

The original purpose of MRI simulators is to obtain an estimation for MRI data representing an object without requiring an MRI device starting from a given model for the object. By means of the computer-implemented method according to the disclosure, however, the MRI simulator may be used in an inverse manner. Rather than obtaining suitable simulated MRI data, the purpose of the MRI simulator in the computer-implemented method according to the disclosure is to iteratively deliver the optimal model for the object given the real measured MRI data. The model obtained in this way then allows to evaluate the at least one material parameter quantitatively without using acquisition sequences specifically designed for the purpose of qMRI.

It is noted that the inversion of the MRI simulator is, in general, not a well-posed problem. Therefore, the computer-implemented method according to the disclosure uses at least two different sets of measured MRI data and correspondingly two different sets of simulated MRI data for the optimization, wherein the error or, in other words, the objective function, depends on both respective deviations between measured and simulated MRI data. Thus, the accuracy of the approach is increased significantly.

In particular, the first measured MRI data may origin from an arbitrary clinical MRI scan. The second acquisition sequence may then be selected in a case specific manner to make sure that the second measured MRI data comprise as much information as possible that is not present in the first MRI data. To achieve this, multiple sequence parameters for the second acquisition sequence may be adapted including, but not limited to, the echo time, the repetition time, the type of the sequence, the physical mechanism of generating the echoes, in particular sequences based gradient echoes versus sequences based on spin echoes, the number of certain HF-pulses, the temporal distance between HF-pulses and so forth. In general, any sequence parameter, which changes the resulting MRI data, may be altered in the second acquisition sequence compared to the first acquisition sequence.

The method according to the disclosure relies on using different acquisition sequences for the first and the second measured MRI data. The more the first measured MRI data and the second measured MRI data differ from each other or, in other words, complement each other in terms of their information content, the higher will be the accuracy of the result. It may also be subject to experiments, how exactly the second acquisition sequence shall be chosen given the first acquisition sequence.

The accuracy and/or reliability of the method may be further increased by taking into account one or more further acquisitions.

According to one or more embodiments, third measured MRI data representing the object is received and a third sequence description specifying a third acquisition sequence used for generating the third measured MRI data is received, wherein the third acquisition sequence is, in particular, different from the first acquisition sequence and different from the second acquisition sequence. For each iteration of the two or more iterations, third simulated MRI data is generated by simulating an MRI acquisition according to the third sequence description based on the model of the respective iteration. The error is determined depending on a deviation of the third simulated MRI data from the third measured MRI data.

In an analog manner, further embodiments based on respective further measured MRI data representing the object and respective further sequence descriptions specifying respective acquisition sequences used for generating the respective further measured MRI data are obtained.

The explanations above and in the following regarding the first measured MRI data and the second measured MRI data hold analogously for the third measured MRI data and the further measured MRI data, as far as applicable. The explanations above and in the following regarding the first simulated MRI data and the second simulated MRI data hold analogously for the third simulated MRI data and the further simulated MRI data, as far as applicable. The explanations above and in the following regarding the first sequence description, the first acquisition sequence, the second sequence description and the second acquisition sequence hold analogously for the third sequence description, the third acquisition sequence, the respective further sequence descriptions and the respective further acquisition sequences, as far as applicable.

According to one or more embodiments, the first measured MRI data and the second measured MRI data are respective raw data in k-space.

In other words it is not required to reconstruct the first measured MRI data and the second measured MRI data into image space before they can be compared to the output of the MRI simulator to compute the error. Therefore, the demands on computational resources like computation time and memory are reduced.

According to one or more embodiments, in step iii) the respective error is computed depending on a measure of similarity or a measure of dissimilarity between the first simulated MRI data and the first measured MRI data and depending on a measure of similarity or a measure of dissimilarity between the second simulated MRI and the second measured MRI data.

According to one or more embodiments, in step iii) the respective error is computed depending on a mean squared error of the deviation of the first simulated MRI data from the first measured MRI data and depending on a mean squared error of the deviation of the second simulated MRI data from the second measured MRI data. For example, the error may be computed as or depending on a sum or a weighted sum of said mean squared errors.

In one or more respective embodiments, the error is computed depending on a mean squared error of the deviation of the third simulated MRI data from the third measured MRI data and depending on a respective mean squared error of the deviation of the respective further simulated MRI data from the respective further measured MRI data, as far as applicable. For example, the error may be computed as a sum or a weighted sum of all respective mean squared errors.

According to one or more embodiments, in step iii) the respective error may be computed depending on a L1-deviation of the first simulated MRI data from the first measured MRI data and depending on a L1-deviation of the deviation of the second simulated MRI data from the second measured MRI data. For example, the error may be computed as or depending on a sum or a weighted sum of said mean squared errors.

According to one or more embodiments, in step iii) the respective error may be computed depending on a structural similarity, SSIM, between the first simulated MRI data and the first measured MRI data and depending on a SSIM between the second simulated MRI data and the second measured MRI data. For example, the error may be computed as or depending on a sum or a weighted sum of said mean squared errors.

According to one or more embodiments, a differentiable MRI simulator may be applied to the model of the respective iteration and the first sequence description in order to generate the respective first simulated MRI data and the differentiable MRI simulator is applied to the model of the respective iteration and the second sequence description in order to generate the respective second simulated MRI data.

Consequently, the adaptation of the model depending on the error is simplified and for example gradient-based optimization algorithms may be used.

According to one or more embodiments, a type of the first acquisition sequence corresponds to a first T1-weighted MRI acquisition, a first T2-weighted MRI acquisition, a first proton density, PD, weighted MRI acquisition, a first fluid attenuated inversion recovery, FLAIR, MRI acquisition or a first diffusion weighted MRI acquisition. In particular, the first sequence description corresponds to a sequence description of the first T1-weighted MRI acquisition, the first T2-weighted MRI acquisition, the first PD-weighted MRI acquisition, the first FLAIR MRI acquisition or the first diffusion weighted MRI acquisition.

According to one or more embodiments, a type of the second acquisition sequence corresponds to a second T1-weighted MRI acquisition, a second T2-weighted MRI acquisition, a second PD-weighted MRI acquisition, a second FLAIR MRI acquisition or a second diffusion weighted MRI acquisition. In particular, the second sequence description corresponds to a sequence description of the second T1-weighted MRI acquisition, the second T2-weighted MRI acquisition, the second PD-weighted MRI acquisition, the second FLAIR MRI acquisition or the second diffusion weighted MRI acquisition.

The T1 relaxation time is the time constant of a process by which the net magnetization returns to its initial maximum value parallel to the main magnetic field. The T1 relaxation time is sometimes also denoted as longitudinal relaxation time, thermal relaxation time or spin-lattice relaxation time. The T2 relaxation time is the time constant of a process by which the transverse components of the magnetization decay. The T2 relaxation time is sometimes also denoted as transverse relaxation time. The T1 relaxation time for a given material is equal to or longer than the T2 relaxation time for this material. For water at a main magnetic field of 1.5T, T1 may be approximately 4000 ms and T2 approximately 2000 ms, for example. For typical biological tissues, T1 may lie in the order of a few hundred ms to 1000 ms, while T2 may lie in the order of 0.1 ms to 100 ms for the same tissues.

The echo time TE corresponds to the time from the respective RF-pulse to the resulting echo, in particular the time between the center of the RF-pulse and the center of the echo. The repetition time TR corresponds to a time period between corresponding consecutive points of a repeating series of pulses and echoes. Thus, TR is in general longer than TE.

Typical values used for TE and TR may for example lie in the order of 1 ms to 200 ms for TE and in the order of 100 ms to 4 s for TR.

The type of the acquisition refers, in particular, to the type of contrast, which may be visualized by the respective MRI data. For example, in a T1-weighted MRI acquisition, the repetition time TR and echo time TE are selected so that the examined materials are differentiated primarily by their T1 relaxation time rather than their T2 relaxation time. In other words, TR and TE are chosen such that T1 is predominantly contrast-enhancing and not T2. This is achieved by selecting a relatively short TR and a relatively short TE. Analogously, in a T2-weighted MRI acquisition, the repetition time TR and echo time TE are selected so that the examined materials are differentiated primarily by their T2 relaxation time rather than their T1 relaxation time. In other words, TR and TE are chosen such that T2 is predominantly contrast-enhancing and not T1. This is achieved by selecting a relatively long TR and a relatively long TE. A PD-weighted MRI acquisition is characterized by a relatively long TR and a relatively short TE.

For example, for a T1-weighted MRI acquisition, TE may lie in the range [1 ms, 30 ms] and TR in the range [100 ms, 700 ms]. For example, for a T2-weighted MRI acquisition, TE may lie in the range [80 ms, 200 ms] and TR in the range [1.5 s, 4 s]. For example, for a PD-weighted MRI acquisition, TE may lie in the range [1 ms, 30 ms] and TR in the range [1.5 s, 4 s].

According to one or more embodiments, the type of the first acquisition sequence differs from the type of the second acquisition sequence, in particular according to the first and the second sequence description.

In such embodiments, the difference between the first acquisition sequence and the second acquisition sequence is particularly pronounced. Thus, the accuracy of the optimization result is increased.

For example, the first acquisition sequence may be a T1-weighted acquisition sequence, while the second acquisition sequence is a T2-weighted acquisition sequence or a PD-weighted acquisition sequence or a FLAIR acquisition sequence or a diffusion weighted acquisition sequence. In further examples, the first acquisition sequence may be a T2-weighted acquisition sequence, while the second acquisition sequence is a T1-weighted acquisition sequence or a PD-weighted acquisition sequence or a FLAIR acquisition sequence or a diffusion weighted acquisition sequence. In further examples, the first acquisition sequence may be a PD-weighted acquisition sequence, while the second acquisition sequence is a T1-weighted acquisition sequence or a T2-weighted acquisition sequence or a FLAIR acquisition sequence or a diffusion weighted acquisition sequence. In further examples, the first acquisition sequence may be a FLAIR acquisition sequence, while the second acquisition sequence is a T1-weighted acquisition sequence or a PD-weighted acquisition sequence or a T2-acquisition sequence or a diffusion weighted acquisition sequence. In further examples, the first acquisition sequence may be a diffusion weighted acquisition sequence, while the second acquisition sequence is a T1-weighted acquisition sequence or a PD-weighted acquisition sequence or a T2-acquisition sequence or a FLAIR acquisition sequence.

According to one or more embodiments, the first sequence description specifies a first echo time and the second sequence description specifies a second echo time, which is different from the first echo time. Alternatively or in addition, the first sequence description specifies a first repetition time and the second sequence description specifies a second repetition time, which is different from the first repetition time.

In such embodiments, the type of the first acquisition sequence and the type of the second acquisition sequence may be the same or may differ from each other. In particular, the difference between the first acquisition sequence and the second acquisition sequence is particularly pronounced. Thus, the accuracy of the optimization result is increased. Therein, the echo time and the repetition time are particularly well suited for differentiating the first acquisition sequence from the type of the second acquisition sequence, since they can be adapted easily within the respective allowable range.

According to one or more embodiments, the model for the object may comprise a respective spatially resolved parameter map for each material parameter of the at least one material parameter.

The spatially resolved parameter map may for example be a three-dimensional parameter map. In this case, the spatially resolved parameter map for a certain material parameter may comprise a respective value for said material parameter for each of a plurality of voxels representing the spatial extension of the object or a part of it.

Adapting the model values depending on the error in step iv) of a given iteration corresponds to adapting the respective values of each material parameter of the at least one material parameter for each of the plurality of voxels depending on the error. Obviously, this does not mean that every value of every voxel for each material parameter is necessarily changed.

In such embodiments, the object may be modelled in a very detailed manner and the quantitative material characterization provides a large amount of information regarding the spatial structure of the object and the potential materials comprised by the object.

In particular, the quantitative material characterization may comprise the respective spatially resolved parameter map for each material parameter of the at least one material parameter of the adapted model of the final iteration.

According to one or more embodiments, the at least one material parameter may comprise a T1-relaxation time and/or a T2-relaxation time and/or a T2*-relaxation time and/or a proton density and/or an apparent diffusion coefficient.

In other words, the model for the object may comprise a T1-relaxation time, for example a spatially resolved T1-map, and/or a T2-relaxation time, for example a spatially resolved T2-map, and/or a T2*-relaxation time, for example a spatially resolved T2*-map, and/or a proton density, for example a spatially resolved PD-map, and/or an apparent diffusion coefficient, for example a spatially resolved map of the apparent diffusion coefficient.

According to a further aspect of the disclosure, a method for quantitative MRI, qMRI, is provided. Therein, first measured MRI data representing an object is generated by an MRI device according to a predefined first acquisition sequence and second measured MRI data representing the object is generated by the MRI device according to a predefined second acquisition sequence. A computer-implemented method according to the disclosure is carried out.

Further implementations of the method for qMRI according to the disclosure follow directly from the various embodiments of the computer-implemented method according to the disclosure and vice versa. In particular, individual features and corresponding explanations as well as advantages relating to the various implementations of the computer-implemented method according to the disclosure can be transferred analogously to corresponding implementations of the method for qMRI according to the disclosure.

According to a further aspect of the disclosure, a data processing system may be configured to carry out a computer-implemented method according to the disclosure is provided.

In the present disclosure, the terms “data processing system” and “at least one data processing device” can be used interchangeably. In particular, a data processing device can be understood to mean a data processing device that contains a processing circuit. The data processing device can therefore, in particular, process data for the purpose of performing computing operations. This may also include operations for performing indexed access to a data structure, for example a look-up table, LUT, as well as a data processing method implemented in hardware.

The data processing device may include, in particular, one or more computers, one or more microcontrollers and/or one or more integrated circuits, for example one or more application-specific integrated circuits, ASIC, one or more field-programmable gate arrays, FPGA, and/or one or more systems-on-a-chip, SoC. The data processing device may also include one or more processors, for example one or more microprocessors, one or more central processing units, CPUs, one or more graphics processing units, GPUs, and/or one or more signal processors, in particular one or more digital signal processors, DSPs. The data processing device may also include a physical or virtual network of computers or other of the mentioned units.

In one or more embodiments, the data processing device may include one or more hardware and/or software interfaces, and/or one or more memory storage units. A storage unit may be a volatile data memory, for example a dynamic random access memory, DRAM, or a static random access memory, SRAM, or a non-volatile data memory, for example a read-only memory, ROM, a programmable read-only memory, PROM, an erasable programmable read-only memory, EPROM, an electrically erasable programmable read-only memory, EEPROM, a flash memory or flash EEPROM, a ferroelectric random access memory, FRAM, a magnetoresistive random access memory, MRAM, or a phase-change random access memory, PCRAM.

According to a further aspect of the disclosure, an MRI system is provided. The MRI system may comprise a data processing system according to the disclosure and an MRI device. The MRI device may be configured to generate the first measured MRI data according to the first acquisition sequence and the second measured MRI data according to the second acquisition sequence.

According to a further aspect of the disclosure, a first computer program comprising first instructions is provided. When the first instructions are executed by a data processing system, the first instructions cause the data processing system to carry out a computer-implemented method according to the disclosure.

The first instructions may be provided as program code, for example. The program code can for example be provided as binary code or assembler and/or as source code of a programming language, for example C, and/or as program script, for example Python.

According to a further aspect of the disclosure, a second computer program comprising second instructions is provided. When the second instructions are executed by an MRI system according to the disclosure, in particular by the data processing system of the MRI system, the second instructions cause the MRI system to carry out a method for qMRI according to the disclosure.

The second instructions may be provided as program code, for example. The program code can for example be provided as binary code or assembler and/or as source code of a programming language, for example C, and/or as program script, for example Python.

According to a further aspect of the disclosure, a computer-readable storage medium, in particular a tangible and/or non-transient computer readable storage medium, storing a first computer program and/or a second computer program according to the disclosure is provided.

The first computer program, the second computer program and the computer-readable storage medium are respective computer program products comprising the first instructions and/or the second instructions.

Further features and feature combinations of the disclosure are obtained from the figures and their description as well as the claims. In particular, further implementations of the disclosure may not necessarily contain all features of one of the claims. Further implementations of the disclosure may comprise features or combinations of features, which are not recited in the claims.

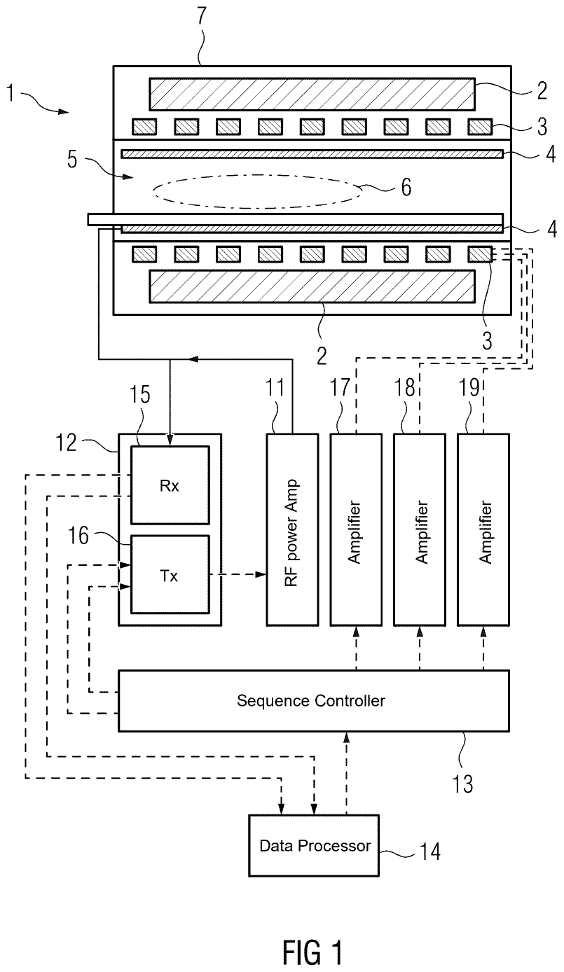

FIG. 1 shows schematically an exemplary embodiment of an MRI system 1 according to the disclosure. The MRI system 1 may comprise an MRI device 7, which may be configured to generate first measured MRI data 20 representing an object 6 according to a predefined first acquisition sequence and second measured MRI data 23 according to a predefined second acquisition sequence. The MRI system 1 may further comprise a data processing system (e.g., processing circuitry, one or more processors) 14 according to the disclosure, which may be configured to carry out a computer-implemented method for determining a quantitative material characterization of the object 6 according to the disclosure based on the first measured MRI data 20 and the second measured MRI data 23.

The MRI device 7 may comprise a housing defining a bore 5 and a main magnet arrangement 2, which may be configured to generate a main magnetic field, also denoted as polarizing magnetic field, within the bore 5. The MRI device 7 may comprise an RF system 4, 11, 12, which may be configured to apply RF pulses to the object 6, in particular a body part of a patient, disposed within the bore 5, and to receive MR signals emitted from the target material. For example, the main magnet arrangement 2 may generate a uniform main magnetic field B0 as the main magnetic field and at least one RF coil 4 of the RF system 4, 11, 12 may emit an excitation field B1.

According to MR techniques, the object 6 is subjected to the main magnetic field, causing the nuclear spins in the target material to precess about the direction of the main magnetic field at their characteristic Larmor frequency. A net magnetic moment Mz is produced in the direction z of the main magnetic field, and the randomly oriented magnetic moments of the nuclear spins cancel out one another in the x-y-plane.

When the object 6 is then subjected to the transmit RF magnetic field, which is for example in the x-y plane and near the Larmor frequency, the net magnetic moment rotates out of the z-direction generating a net in-plane magnetic moment, whose projection rotates in the x-y plane with the Larmor frequency. In response, MR signals are emitted by the excited spins when they return to their state before the excitation. The emitted MR signals are detected, for example by the at least one RF coil 4 and/or one or more dedicated detection coils, digitized in a receiver channel 15 of an RF controller 12 of the RF system 4, 11, 12, and may be processed, for example by the data processing system 14, to reconstruct an MR image using for example a known reconstruction technique.

In particular, gradient coils 3 of the MRI device 7 may produce magnetic field gradients Gx, Gy, and Gz for position-encoding of the MR signals. Accordingly, MR signals are emitted only by such nuclei of the target material, which correspond to the particular Larmor frequency. For example, Gz is used together with a bandwidth-limited RF pulse to select a slice perpendicular to the z-direction and consequently may also be denoted as slice selection gradient. In alternative examples, Gx, Gy, and Gz may be used in any predefined combination with a bandwidth-limited RF pulse to select a slice perpendicular to the vector sum of said gradient combination. The gradient coils 3 may be supplied with current by respective amplifiers 17, 18, 19 for generating the respective gradient fields in x-direction, y-direction, and z-direction, respectively. Each amplifier 17, 18, 19 may include a respective digital-to-analog converter, which may be controlled by a sequence controller 13 to generate respective gradient pulses at predefined time instances.

The sequence controller 13 may control the generation of RF pulses by an emitter (transmission—Tx) channel 16 of the RF controller 12 and an RF power amplifier 17 of the RF system 4, 11, 12.

The data processing system 14 may receive the real and imaginary parts from analog-digital converters of the receiver channel 15 and reconstruct the MR image based on them according to a known technique. Additionally, or alternatively, the data processing system 14 may be configured to control the MRI system 1 and/or one or more components therein.

It is noted that the components of the MRI device 7 can also be arranged differently from the arrangement shown in FIG. 1. For example, the gradient coils 3 may be arranged inside the bore 5, similar as shown for the at least one RF coil 4. It is further noted that each component of the MRI device 7 may include other elements which are required for the operation thereof, and/or additional elements for providing functions other than those described in the present disclosure.

In an exemplary embodiment, one or more components (e.g., 7, 11, 12, 13, 14, 15, 16, 17, 18, and/or 19) of the MRI system 1 may comprise processing circuitry configured to perform one or more respective functions/operations of the component(s). For example, the data processing system 14 may include processing circuitry configured to perform one or more operations/functions (e.g., data processing, controlling the MRI system 1 and/or one or more other components therein) of the data processing system 14. The data processing system 14 may include one or memories configured to store data and/or instructions. Alternatively, or additionally, the data processing system 14 may be configured to access one or more external memories to access and/or store data and/or instructions. For example, the data processing system 14 may include one or more processors that are configured to execute instructions stored in the memory and accessed by the one or more processors to perform one or more functions and/or operations of the data processing system 14.

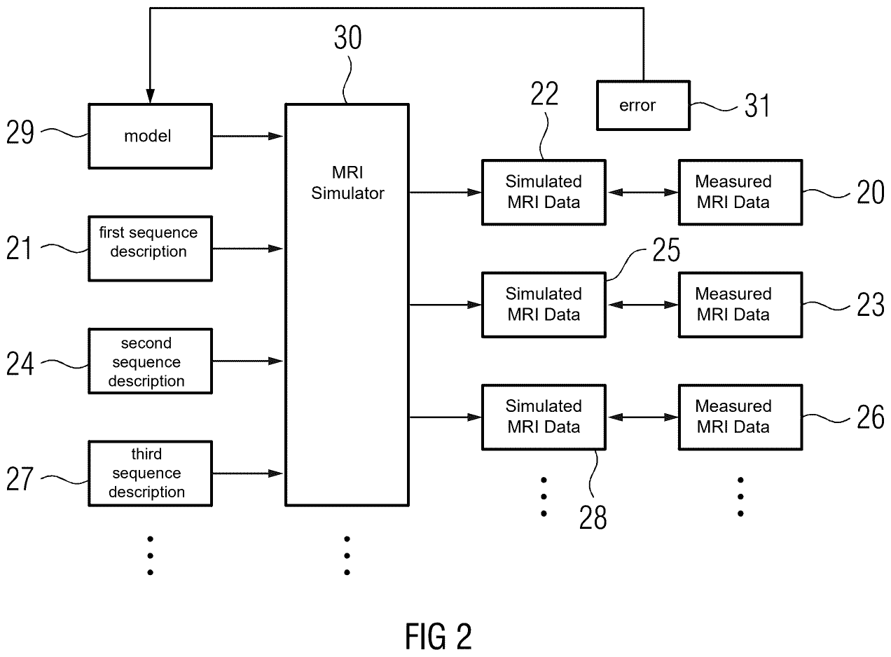

FIG. 2 shows a schematic block diagram of an exemplary embodiment of a computer-implemented method for determining a quantitative material characterization of the object 6 according to the disclosure.

Therein, the first measured MRI data 20 and a first sequence description 21, for example according to the pulseq standard, specifying a first acquisition sequence used for generating the first measured MRI data 20 is received. Furthermore, the second measured MRI data 23 and a second sequence description 24 specifying a second acquisition sequence used for generating the second measured MRI data 23 is received.

A model 29 for the object 6 comprising respective model values for at least one material parameter of the object 6 is received, in particular an initial version of the model 29 comprising respective predefined initial model values for the at least one material parameter. The at least one material parameter may comprise, for example, a T1-relaxation time and/or a T2-relaxation time and/or a T2*-relaxation time and/or a proton density PD and/or an apparent diffusion coefficient. In particular, the model 29 may comprise a respective spatially resolved parameter map for each material parameter of the at least one material parameter.

Furthermore, an MRI simulator 30, in particular a differential MRI simulator 30, is provided. The MRI simulator 30 may be, for example, a software tool, which configured to simulate respective MRI data based on the model 29 and a corresponding sequence description. Thus, the MRI simulator 30 may be used to optimize an objective function, which depends on respective deviations between the measured MRI data 20, 23 and the corresponding simulated MRI data 22, 25, iteratively by varying the model 29, in particular the values of the spatially resolved parameter maps.

To this end, for each iteration of two or more iterations, steps i) to iv) are carried out, wherein in step i), the first simulated MRI data 22 may be generated by the MRI simulator 30 by simulating an MRI acquisition according to the first sequence description 21 based on the model 29 of the respective iteration. In step ii), the second simulated MRI data 25 may be generated by the MRI simulator 30 by simulating an MRI acquisition according to the second sequence description 24 based on the model 29. In step iii), an error 31 may be determined, which depends on a deviation of the first simulated MRI data 22 from the first measured MRI data 20 and on a deviation of the second simulated MRI data 25 from the second measured MRI data 23. In step iv), the model 29 may be adapted by adapting the model values depending on the error 31.

In the two or more iterations, the model 29 corresponds to the predefined initial version of the model 29 for an initial iteration of the two or more iterations. For all other iterations of the two or more iterations, the model 29 of the respective iteration corresponds to the adapted model 29 of the respective preceding iteration. The quantitative material characterization may be determined depending on the adapted model 29 of a final iteration of the two or more iterations. In particular, the iterations are continued until the error 31 is equal to or less than a predefined maximum error. The corresponding iteration where this is the case is the final iteration of the two or more iterations.

It is noted that the described method may, in respective iterations, be extended to include further measured MRI data and corresponding further simulated MRI data and process them in the same way as explained for the first and second measured MRI data 20, 23 and the first and second simulated MRI data 22, 25, respectively. The error 31 then depends on all respective deviations between the measured MRI data and the simulated MRI data.

This is indicated for third measured MRI data 26 in FIG. 2. In this case, the third measured MRI data 26 and a third sequence description 27 specifying a third acquisition sequence used for generating the third measured MRI data 26 are received. For each iteration of the two or more iterations, third simulated MRI data 28 may be generated by the MRI simulator 30 by simulating an MRI acquisition according to the third sequence description 27 based on the model 29 of the respective iteration. The error 31 may be determined depending on a deviation of the third simulated MRI data 28 from the third measured MRI data 26.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A computer-implemented method for determining a quantitative material characterization of an object, the method comprising:
receiving first measured magnetic resonance imaging (MRI) data representing the object and receiving a first sequence description specifying a first acquisition sequence usable for generating the first measured MRI data;
receiving second measured MRI data representing the object and a second sequence description specifying a second acquisition sequence usable for generating the second measured MRI data;
for each iteration of two or more iterations:
generating first simulated MRI data by simulating an MRI acquisition according to the first sequence description based on a model for the object comprising respective model values for at least one material parameter of the object;
generating second simulated MRI data by simulating an MRI acquisition according to the second sequence description based on the model;
determining an error, which depends on a deviation of the first simulated MRI data from the first measured MRI data and on a deviation of the second simulated MRI data from the second measured MRI data; and
adapting the model by adapting the model values depending on the error, wherein, based on a respective iteration being an initial iteration of the two or more iterations, the model of the respective iteration corresponds to an initial model for the object comprising respective predefined initial model values for the at least one material parameter, and, otherwise, the model of the respective iteration corresponds to the adapted model of a respective preceding iteration; and
determining the quantitative material characterization based on the adapted model of a final iteration of the two or more iterations.

2. The computer-implemented method according to claim 1, wherein a type of the first acquisition sequence differs from a type of the second acquisition sequence.

3. The computer-implemented method according to claim 2, wherein:
the type of the first acquisition sequence corresponds to a first T1-weighted MRI acquisition, a first T2-weighted MRI acquisition, a first proton density (PD)-weighted MRI acquisition, a first fluid attenuated inversion recovery (FLAIR) MRI acquisition, or a first diffusion weighted MRI acquisition; and/or
the type of the second acquisition sequence corresponds to a second T1-weighted MRI acquisition, a second T2-weighted MRI acquisition, a second PD-weighted MRI acquisition, a second FLAIR MRI acquisition, or a second diffusion weighted MRI acquisition.

4. The computer-implemented method according to claim 1, wherein:
the first sequence description specifies a first echo time and the second sequence description specifies a second echo time different from the first echo time; and/or
the first sequence description specifies a first repetition time and the second sequence description specifies a second repetition time different from the first repetition time.

5. The computer-implemented method according to claim 1, wherein the model for the object comprises a respective spatially resolved parameter map for each material parameter of the at least one material parameter.

6. The computer-implemented method according to claim 1, wherein the at least one material parameter comprises: a T1-relaxation time, a T2-relaxation time, a T2*-relaxation time, a proton density (PD), and/or an apparent diffusion coefficient.

7. The computer-implemented method according to claim 1, wherein the generating the first simulated MRI data comprises: applying a differentiable MRI simulator to the model of the respective iteration and the first sequence description in order to generate the respective first simulated MRI data, and applying the differentiable MRI simulator the model of the respective iteration and the second sequence description in order to generate the respective second simulated MRI data.

8. The computer-implemented method according to claim 1, wherein determining the error comprises computing the respective error based on: a mean squared error of the deviation of the first simulated MRI data from the first measured MRI data, and a mean squared error of the deviation of the second simulated MRI data from the second measured MRI data.

9. The computer-implemented method according to claim 1, wherein the two or more iterations are terminated after the final iteration of the two or more iterations, wherein the error of the final iteration is equal to or less than a predefined maximum error.

10. The computer-implemented method according to claim 1, wherein the first measured MRI data and the second measured MRI data are respective raw data in k-space.

11. The computer-implemented method according to claim 1, further comprising:
receiving third measured MRI data representing the object and receiving a third sequence description specifying a third acquisition sequence usable for generating the third measured MRI data; and
for each iteration of the two or more iterations, generating third simulated MRI data by simulating an MRI acquisition according to the third sequence description based on the model of the respective iteration, the error being determined based on a deviation of the third simulated MRI data from the third measured MRI data.

12. A method for quantitative magnetic resonance imaging (MRI), comprising:
generating, by an MRI device according to a predefined first acquisition sequence, first measured MRI data representing an object;
generating, by the MRI device according to a predefined second acquisition sequence, second measured MRI data representing the object; and
performing the computer-implemented method according to claim 1.

13. A data processing system comprising:
one or more processors; and
memory storing instructions that, when executed by the one or more processors, cause the system to perform the computer-implemented method according to claim 1.

14. A magnetic resonance imaging (MRI) system comprising:
a data processing system including one or more processors and memory storing instructions that, when executed by the one or more processors, cause the system to perform the computer-implemented method according to claim 1; and
an MRI device configured to generate the first measured MRI data according to the first acquisition sequence and the second measured MRI data according to the second acquisition sequence.

15. At least one non-transitory computer-readable medium comprising instructions stored thereon, that when executed by one or more processors, cause the one or more processors to perform the computer-implemented method according to claim 1.
